(19) United States
(12) Patent Application Publication
(10) Pub. No.: US 2006/0273385 A1
(43) Pub. Date: Dec. 7, 2006

(54) Trenched MOSFET device with contact trenches filled with tungsten plugs

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Semiconductor Sdn. Bhd.

(21) Appl. No.: 11/363,824

(22) Filed: Feb. 28, 2006

Related U.S. Application Data
(63) Continuation-in-part of application No. 11/147,075, filed on Jun. 6, 2005.

(51) Int. Cl. H01L 29/78; H01L 21/336

(52) U.S. Cl. 257/330; 257/797; 438/589; 438/401; 438/454; 438/270

(57) ABSTRACT

A trenched semiconductor power device that includes a trenched gate disposed in an extended continuous trench surrounding a plurality of transistor cells in an active cell area and extending as trench-gate fingers to intersect with a trenched gate under the gate metal runner at a termination area. At least one of the trench-gate fingers intersects with the trenched gate under the gate metal runner near the termination area having trench intersection regions vulnerable to have a polysilicon void developed therein. At least a gate contact trench opened through an insulation layer covering the semiconductor power device wherein the gate contact trench penetrating from the insulation layer and extending into the gate polysilicon and the gate contact trench is opened in an area away from the trench intersection regions.

This patent application is a Continuation in Part (CIP) Application of a co-pending application Ser. No. 11/147,075 filed by a common Inventor of this Application on Jun. 6, 2005 with a Serial Number. The Disclosures made in that Application is hereby incorporated by reference.

### BACKGROUND OF THE INVENTION

1. Field of the Invention

This invention relates generally to the cell structure, device configuration and fabrication process of power semiconductor devices. More particularly, this invention relates to a novel and improved cell structure, device configuration and improved process for fabricating a trenched semiconductor power device with improved increased cell density by reducing a gate to source contact critical dimension (CD) requirement.

2. Description of the Related Art

In order to further increase the cell density in a semiconductor power device, the MOSFET devices are manufactured with trenched source contact plugs with the plugs formed with tungsten to reduce the distance between the gate and the source contact. Specifically, the Applicant of this Patent Application has filed another patent application Ser. No. 11/147,075 on Jun. 6, 2005 to improve the cell density by reducing the distance between the source contacts and the trenched gates 20. An improved configuration of a MOSFET device is shown in FIG. 1 wherein the distance between the source contacts 45 and the trenched gates 20 are reduced by placing the source contact 45 in the source-body contact trenches opened in an oxide layer 35. As shown in FIG. 1A, the source-body contact trenches 45 extend into the body regions 25 thus contacting both the source regions 30 and the body regions 25 to provide improved and more reliable electric contacts. The difficulties of the conventional technologies to further increase the cell density due to the requirement of a large critical dimension (CD) between the source contacts and the trench gates is relaxed.

However, with tungsten plugs implemented as source and gate contact, there are still additional technical challenges confronted with such device configuration and manufacturing processes. Specifically, before refilling the trenches with tungsten plugs, a contact-silicon etch is required after the contact oxide etch to first open up insulating dielectric layer. However, the contact silicon etch may etch through trench gate polysilicon with a T-intersection layout due to polysilicon hole formation during the process of a polysilicon deposition in certain trenched gate area as shown in FIG. 1B as the result of two dimensional polysilicon deposition. With such etch through holes penetrated through the polysilicon gates, the tungsten plug when filling in the contact trenches also filling into such etch-through holes thus generating an electrical short circuit through the gate oxide and the drain at trench bottom shown in FIGS. 1C and 1D. The etch-through problem with the holes penetrating through the polysilicon layer thus often causes a gate-to-drain shortage and raising device performance reliability issues.

Furthermore, after filling the source contact trenches with the tungsten plugs and etching back, the processing steps proceed with the deposition and patterning of the source metal 60 and gate pad 70 followed by applying a wire bonding process. However, there is another processing difficulty due to the fact that the wire-bonding machines cannot differentiate the source metal 60 from the gate pad 70 during a wire bonding process. There is no such difficulty when a conventional processing flow is applied. FIG. 2A shows a top view of a MOSFET device prior to the wire bonding process when a conventional configuration is implemented with the cross sectional view shown in FIG. 2B. The source metal 60′ has a much rougher and has less reflectance and darker top surface than the gate metal 70′. It is very convenient to process the wire-bonding process by recognizing that the source metal 60′ has a darker top surface than the gate metal 70′. However, the top surface of the source metal 60 is almost fully planarized across the entire surface when tungsten plugs are implemented for source contact as shown in FIG. 2C. With tungsten source contact plugs, excellent metal coverage process and better planarization is now readily achievable as shown in FIG. 2C. A top view of the device as shown in FIG. 2D is different from the top surface shown in FIG. 2A where a single metal contact having much rougher source metal surface than gate metal surface as result of poor metal step coverage. Because of the improved planarized surface provided by the tungsten plug technique, it is difficult for pattern recognition of gate metal and source metal pads during wire bonding. As the source metal and gate metal both have same smooth top surface and similar reflectance, the wire bonding equipment cannot differentiate gate metal and source metal pads as the top surfaces for both of these areas have the same color.

Therefore, there is still a need in the art of the semiconductor device fabrication, particularly for trenched power MOSFET design and fabrication, to provide a novel cell structure, device configuration and fabrication process that would resolve these difficulties and design limitations.

### SUMMARY OF THE PRESENT INVENTION

It is therefore an object of the present invention to provide new and improved semiconductor power device configuration, such as a MOSFET device that comprises tungsten contact plugs disposed in trenches disposed away from the trench intersection areas. By opening contact trenches away from the trench intersection areas, the problem of etching through polysilicon holes due to the etching process in opening the trenches for contact plugs is minimized. The problems as that encountered in the manufacturing processes as discussed above are resolved.

Another aspect of the present invention is to pattern the source and gate metal with either a holes at interfacing corners and diagonal corners to provide as landmarks for area recognitions. The landmarks on the metal layer thus enhance the wire bonding process in manufacturing the semiconductor power device.

Another aspect of the present invention is to pattern and separate the source and gate metals with a color area through deposition of oxide, nitride, SiON, or a layer composed of combination of materials. The colored layer disposed between the source metal and gate metal serves the function of area recognition by a wire-bonding machine. The separation color area thus enhances the wire bonding process in manufacturing the semiconductor power device. The problems and limitations as discussed above are therefore resolved.

Briefly, in a preferred embodiment, the present invention discloses a trenched semiconductor power device that includes a trenched gate disposed in an extended continuous trench surrounding a plurality of transistor cells in an active cell area and extending as trench-gate fingers to intersect with a trenched gate under the gate metal runner at a termination area. At least one of the trench-gate fingers intersects with the trenched gate under the gate metal runner near the termination area having trench intersection regions vulnerable to have a polysilicon void developed therein. At least a gate contact trench opened through an insulation layer covering the semiconductor power device wherein the gate contact trench penetrating from the insulation layer and extending into the gate polysilicon and the gate contact trench is opened in an area away from the trench intersection regions. In a preferred embodiment, the trench intersection regions constitute a T-shaped intersection region. In a preferred embodiment, the gate contact trench is filled with a conductive gate contact plug. In a preferred embodiment, the gate contact trench is filled with a tungsten gate contact plug. In a preferred embodiment, the gate contact trench is filled with a tungsten gate contact plug surrounded with a Ti/TiN barrier layer. In a preferred embodiment, the trenched gate under the gate metal runner is configured as an open stripe extending from and intersecting to the trench-gate fingers as an L-shaped trenched gate under the gate metal runner with the gate contact trench opened at a distance S away from an near edge of each of the trench-gate fingers where S is greater than half of a width of the trench-gate fingers. In a preferred embodiment, the trenched gate under the gate metal runner is configured as an open stripe extending from and intersecting to the trench-gate fingers as an expanded square-shaped trenched gate under the gate metal runner with the gate contact trench opened at a distance S away from an intersecting edge of each of the trench-gate fingers with the expanded square shaped trenched gate under the gate metal runner where S is greater than a width of the trench-gate fingers. In a preferred embodiment, the trenched gate under the gate metal runner is configured as a no-open-end trenched gate under the gate metal runner perpendicularly intersecting to the trench-gate fingers with the gate contact trench opened at a distance S away from an intersecting edge of each of the trench-gate fingers with the no-open-end trenched gate under the gate metal runner where S is greater than half of a width of the trench-gate fingers. In a preferred embodiment, the trenched gate under the gate metal runner is configured as an open stripe extending from and intersecting to the trench-gate fingers as an expanded rectangular-shaped trenched gate under the gate metal runner with the gate contact trench opened at a distance S away from an intersecting edge of each of the trench-gate fingers with the expanded rectangular shaped trenched gate under the gate metal runner where S is greater than a width of the trench-gate fingers. In a preferred embodiment, the trenched gate underneath the gate metal runner is configured as an open stripe trenched gate extending from and having a greater width than the trench-gate fingers wherein the open stripe allowing a body region, i.e., the region 125 in FIG. 3A, disposed adjacent to a source region of the semiconductor power device connecting to a body, i.e., region 126 in FIG. 3A, underneath a metal field plate served by the gate runner metal. In a preferred embodiment, the trenched gate underneath the gate metal runner is configured as an open stripe extending from and intersecting to the trench-gate fingers as an L-shaped trenched gate underneath the gate metal runner and having a greater width than the trench-gate fingers wherein the L-shaped open stripe allowing a body region disposed adjacent to a source region of the semiconductor power device connecting to a body-dopant region underneath a metal field plate served by gate metal runner.

This invention further discloses a trenched semiconductor power device that includes a trenched gate surrounded by a source region encompassed in a body region above a drain region disposed on a bottom surface of a substrate, wherein the semiconductor power device further includes at least two contact trenches opened through an insulation layer covering the semiconductor device wherein the contact trenches extending into the trenched gate and the body region and filled with a gate contact plug and a source contact plug for electrically contact respectively to a gate metal and a source metal disposed on top of the insulation layer wherein the gate metal and source metal further include a pattern recognition mark for wire bonding. In a preferred embodiment, the pattern recognition further includes a TiN/dielectric layer formed on the source metal and gate metal for providing a pattern recognition mark for wire bonding. In a preferred embodiment, the pattern recognition further includes at least a pattern-recognition hole formed on predefined location of the gate metal or the source metal for providing a pattern recognition mark for wire bonding. In a preferred embodiment, the pattern recognition further includes a pattern-recognition hole formed on a intersection corner between the gate metal and source metal of the metal layer for providing a pattern recognition mark for wire bonding. In a preferred embodiment, the pattern recognition further includes a first pattern-recognition hole formed on a intersection corner between the gate metal and source metal and a second pattern recognition hole on a source metal corner diagonally opposite the first pattern-recognition hole in the metal layer for providing a pattern recognition mark for wire bonding.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIGS. 1A to 1B are respectfully a cross sectional view and a top view of a MOSFET device configuration to increase the transistor cell density disclosed in a related Patent Application of this invention by the Applicant of this invention.

FIGS. 1C to 1D are cross sectional views for illustrating holes in polysilicon layer commonly developed in the T-intersections of the trenched gates and an etch through hole that leads to potential reliability problems.

FIGS. 2A and 2B are respectfully a top view and a cross sectional view of a conventional MOSFET device showing a rough top surface of the source metal and a smooth top surface of the gate pad.

FIGS. 2C and 2D are respectfully a cross sectional view and a top view of a MOSFET device implemented with tungsten source contact plugs filling the source contact trenches thus enabling an excellent planarization in providing a smooth top surface for both the source metal and the gate pad.

FIG. 3A shows a cross sectional view and FIGS. 3B and 3C are two top views of an L-shaped trench and stripe shape trenches respectfully of the present invention.

FIGS. 4A and 4B are a top view and a cross sectional view respectfully of a MOSFET device configuration of this invention with open contacts to avoid T-intersection regions thus preventing the development of polysilicon holes.

FIG. 5 is a top view for showing metal holes on the corner of the source metal and the gate pad of this invention for wire-bonding area recognition.

FIG. 6 is a top view for showing TiN or TiN/Dielectric deposition on the source or gate metal according to an embodiment of this invention to darken the top surface for wire-bonding area recognition.

FIG. 7 is a cross sectional view of the MOSFET device of FIG. 6 with TiN deposited on top of the source and gate metal to enhance a process of wire-bonding area recognition.

FIG. 8 is a cross sectional view of the MOSFET device of FIG. 6 with TiN deposited on top of the source and gate metal and further covered with a passivation layer to enhance a process of wire-bonding area recognition.

FIGS. 9A to 9E are a serial of side cross sectional views for showing the processing steps for fabricating the MOSFET devices as shown in FIGS. 3 to 4C.

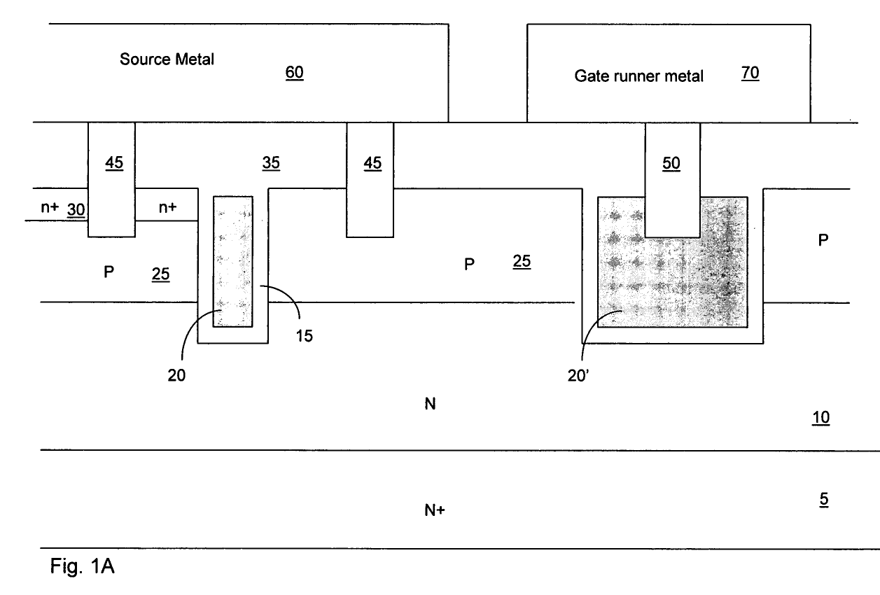

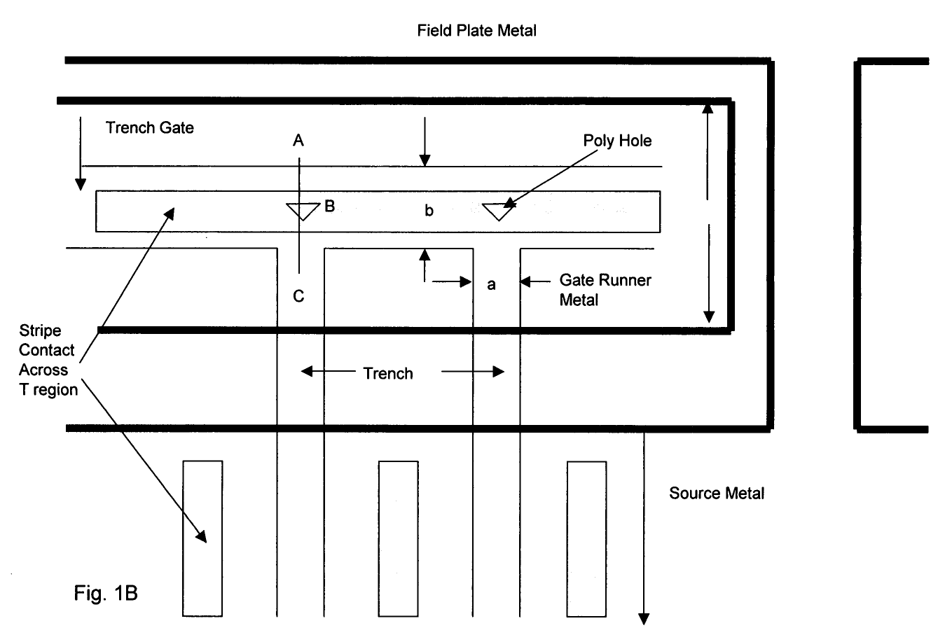

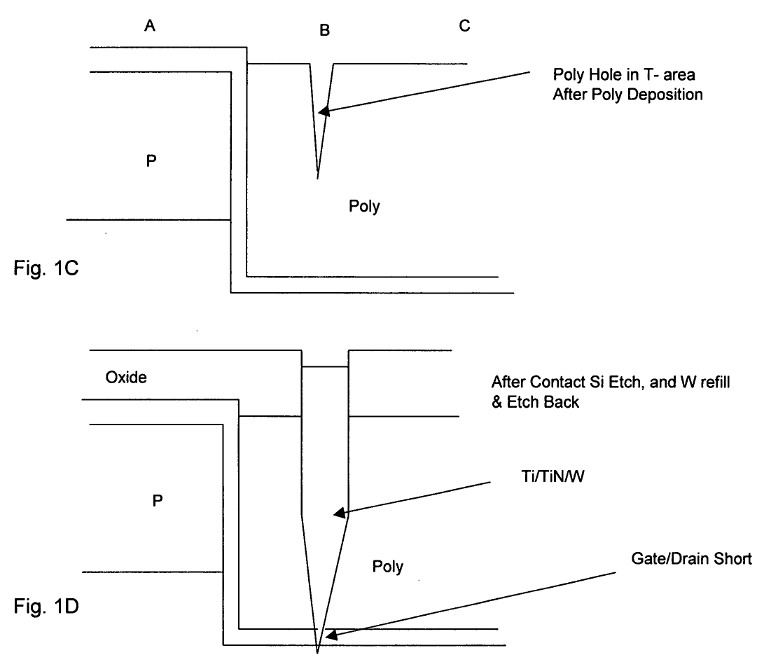

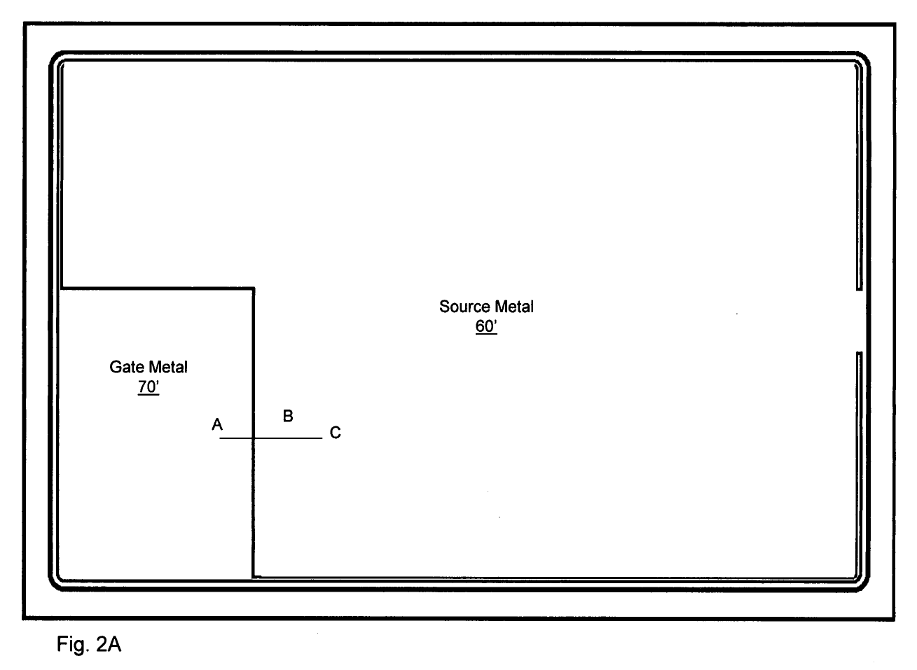

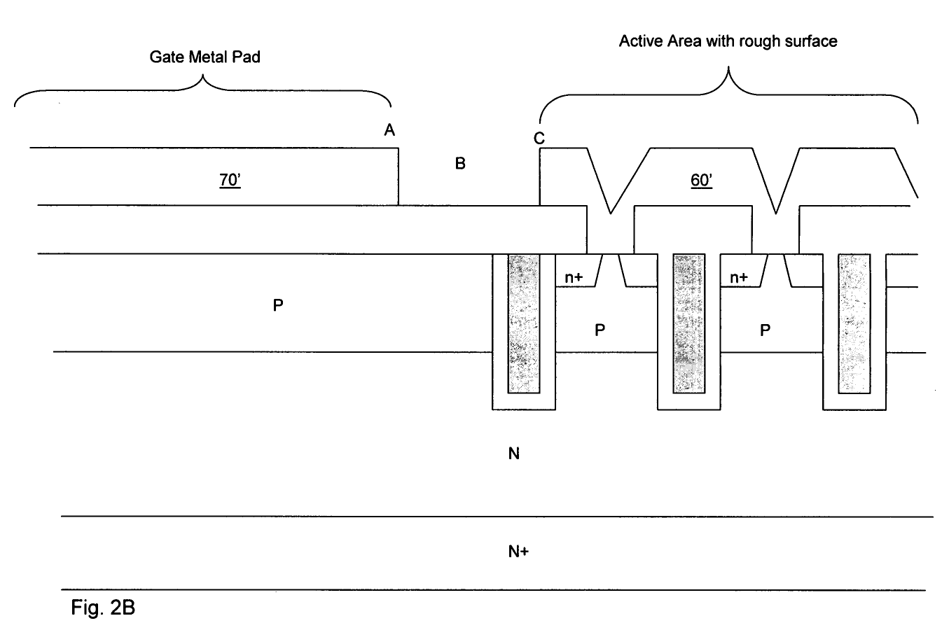

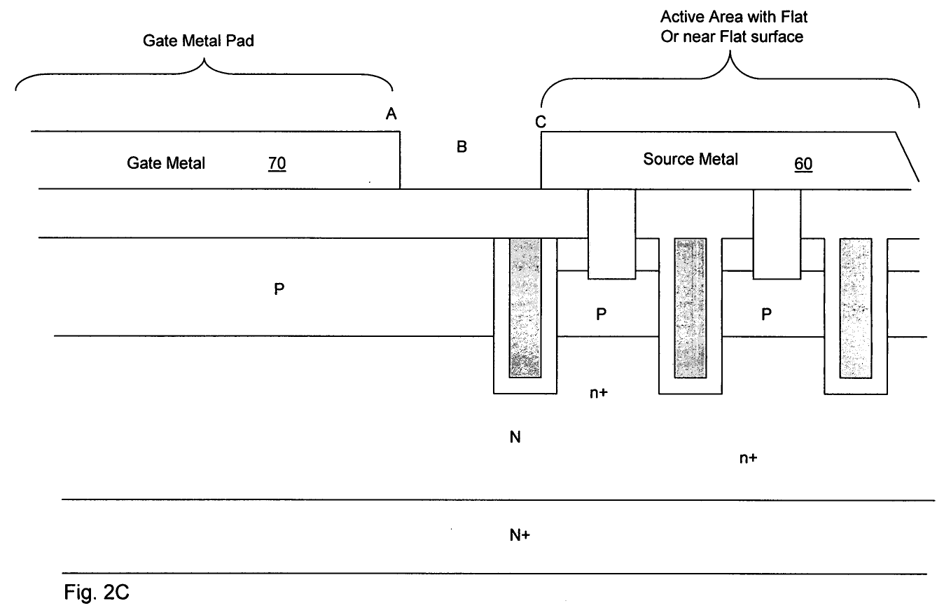

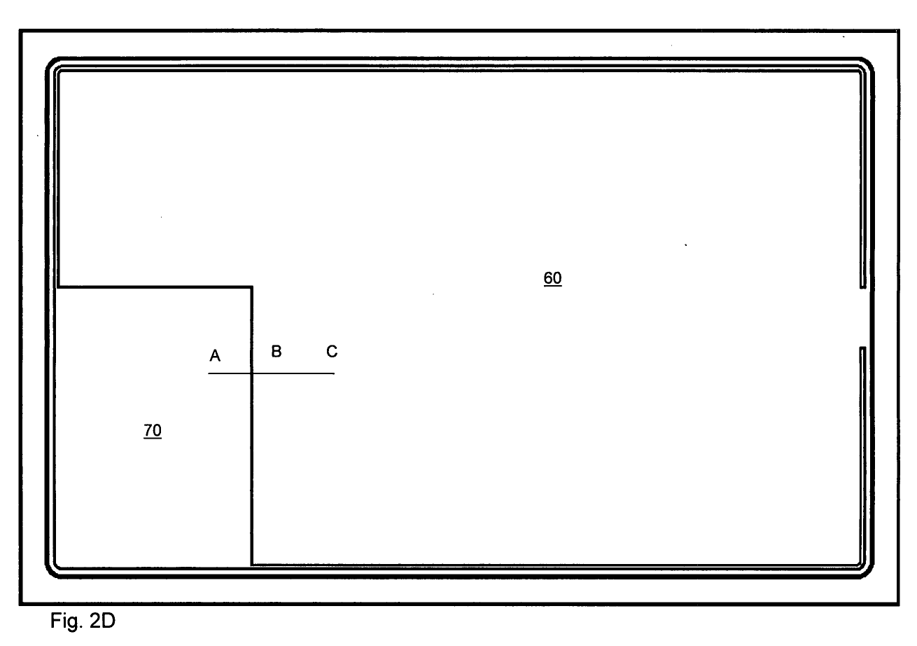

### DETAILED DESCRIPTION OF THE PREFERRED EMBODIMENT

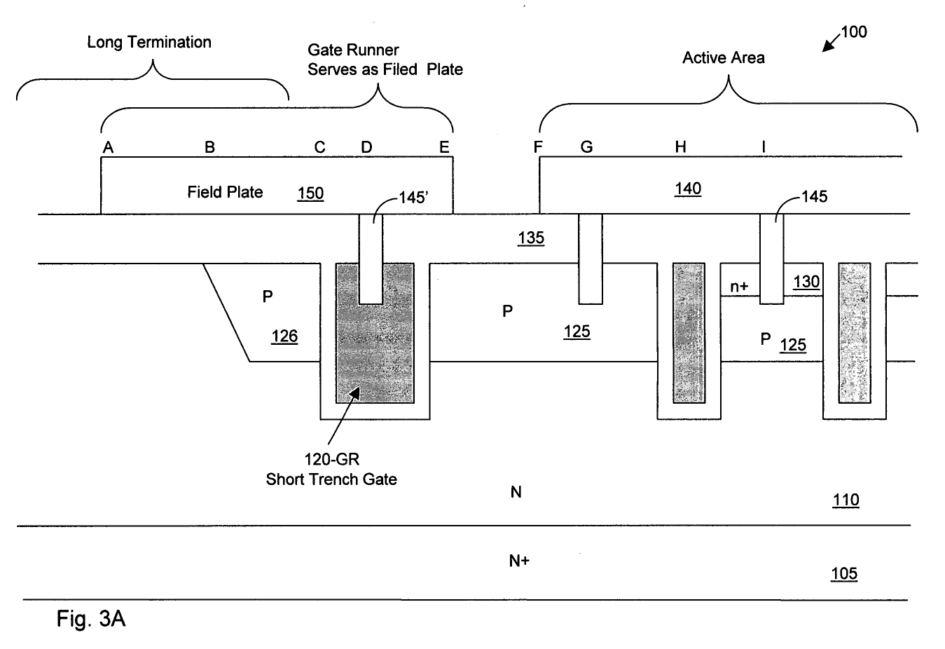

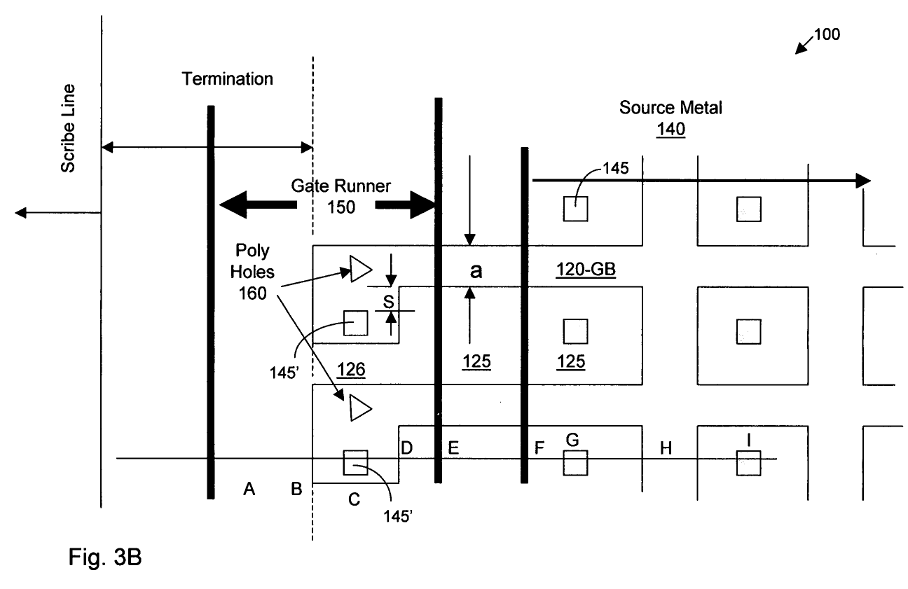

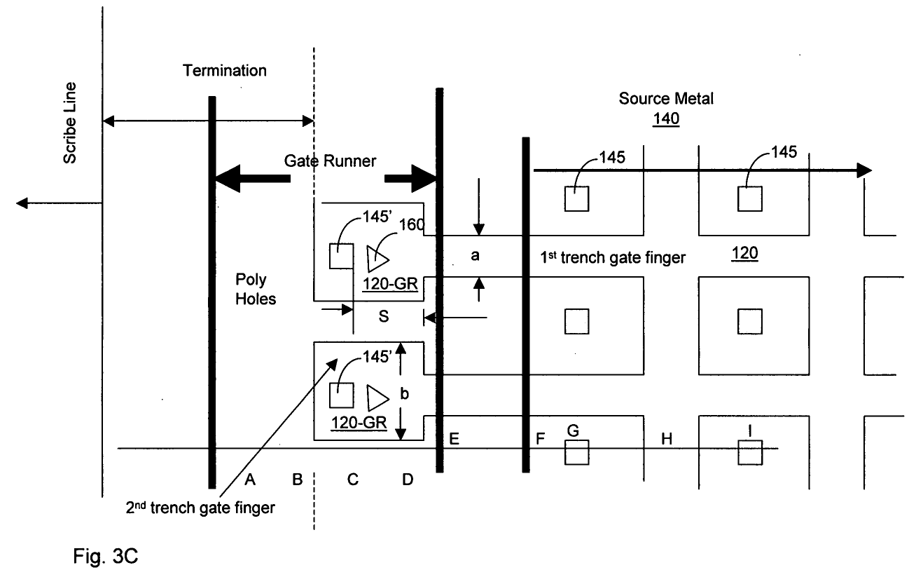

Please refer to FIGS. 3A to 3B for the side cross sectional view and top view of a first preferred embodiment of this invention. A metal oxide semiconductor field effect transistor (MOSFET) device 100 is supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 120. The top surface of the semiconductor substrate extending over the top of the trenched gate, the P body regions 125 and the source regions 130 are covered with a NSG and a BPSG protective layers 135. A source metal layer 140 and gate metal layer (not shown) are formed on top of the protective insulation layer 135.

For the purpose of improving the source contact to the source regions 130, a plurality of trenched source contact filled with a tungsten plug 145 that is surrounded by a barrier layer Ti/TiN. The contact trenches are opened through the NSG and BPSG protective layers 135 to contact the source regions 130 and the P-body 125. Then a conductive layer with low resistance (not shown) is formed over the top surface to contact the trenched source contact 145. A top contact layer 140 is then formed on top of the source contact 145. The top contact layer 140 is formed with aluminum, aluminum-cooper, AlCuSi, or Ni/Ag, Al/NiAu, AlCu/NiAu or AlCuSi/NiAu as a wire-bonding layer. The low resistance conductive layer (not shown) sandwiched between the top wire-bonding layer 140 and the top of the trenched source-plug contact 145 is formed to reduce the resistance by providing greater area of electrical contact.

In order to further increase the active areas for ultra high cell density MOSFET device, a specially configured termination structure is disclosed in the present invention. The termination includes a planar field plate 150 formed on top of a shortened gate runner 120-GR that is shorter than one micrometer. In order to assure good contact to the gate runner 120-GR, a trenched gate runner contact plug 145′ is formed on top of the gate runner 120-GR. The gate-runner contact plug 145′ is composed of tungsten surrounded by a Ti/TiN barrier layer.

Referring to FIG. 3B for a top view of an exemplary embodiment of this invention to prevent a source to drain short circuit problem. This source-to-drain short circuit problem may occur due to the development of polysilicon holes at the T-intersection. The T-intersection is between the trenches in forming the trenched gate 120 and the shortened trench gate 120-GR below the gate runner 150 at the termination area. The trenches 120 extend to the termination area as trench-gate fingers and form an L-shaped intersection with the termination trench 120-GR. The trenches 120 formed as trench-gate fingers have a gate width of “a”. The polysilicon holes 160 commonly develop at the intersection points between the trenches 120 and the termination trenches 120-GR. In order to avoid these polysilicon holes 160, the trenched source contact plugs 145 and the trenched gate contact plugs 145′ are opened away from the intersection points. As shown in FIG. 3B, the trenched gate contact plugs 145′ are formed having at least a distance of S away from the inner edge of the trench-fingers 120 where S is greater than half of the trench width a, i.e., S>(½)*a. The trenched gate contact plugs are disposed near the edges of the L-shaped gate-runner trenched gate 120-GR opposite to the trench-gate fingers 120. FIG. 3C is an alternate embodiment where the trenches are formed with a stripe shape. In order to avoid the trenched contact plugs 145′ filling into the polysilicon holes 160, the gate contact openings 145′ are opened near the edge of the expanded stripes 120-GR away from the intersections of the trenches 120 with the gate runner trenches 120-GR in extending into the termination area. The trenched contact plugs 145 are disposed at a distance S away from the intersection point between the trench-gate fingers 120 and the trenched gate runner 120-GR where S>a where a is the width of the trench-gate finger 120. Referring to FIGS. 3A and 3B again, the P-body region 125 in the source region is connected to the P-body region 126 underneath the gate metal runner 150 serving the function of a field plate. As shown in FIG. 3B, the open area as an extended body dopant region 126 allows the P-body region in the source region to connect to the body dopant region 126 underneath the gate-runner metal 150. Connection of the body region 125 in the source region to the P-body region 126 underneath the gate metal runner 150 prevents the P-body region 126 from becoming floating that leads to a low breakdown (BV) voltage. The gate metal runner 150 serves the function of a field plate because the gate is kept at a same potential as the source at a breakdown measurement.

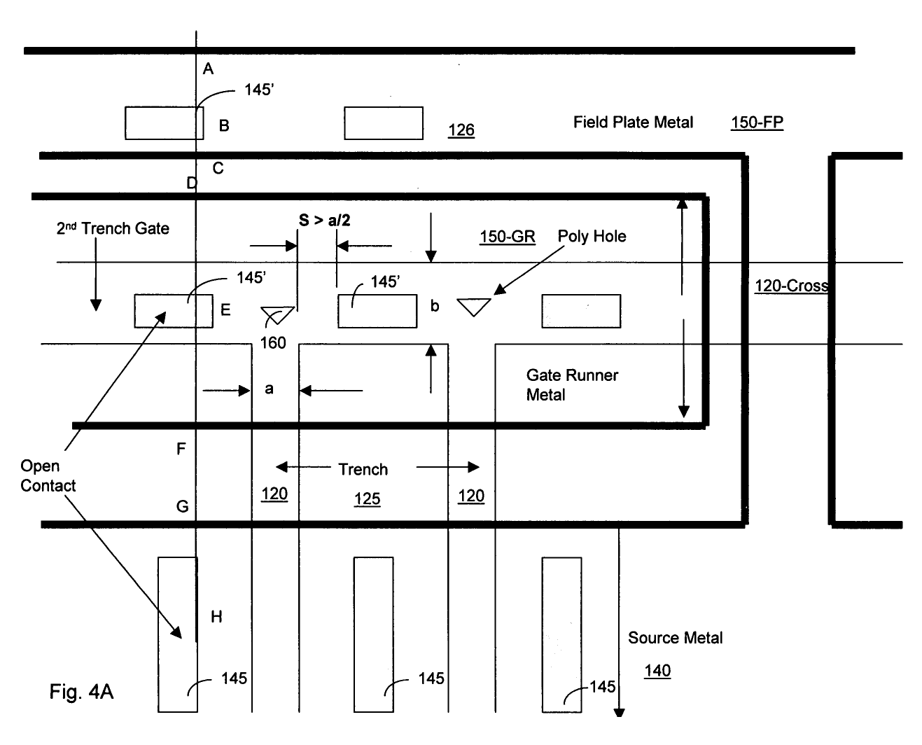

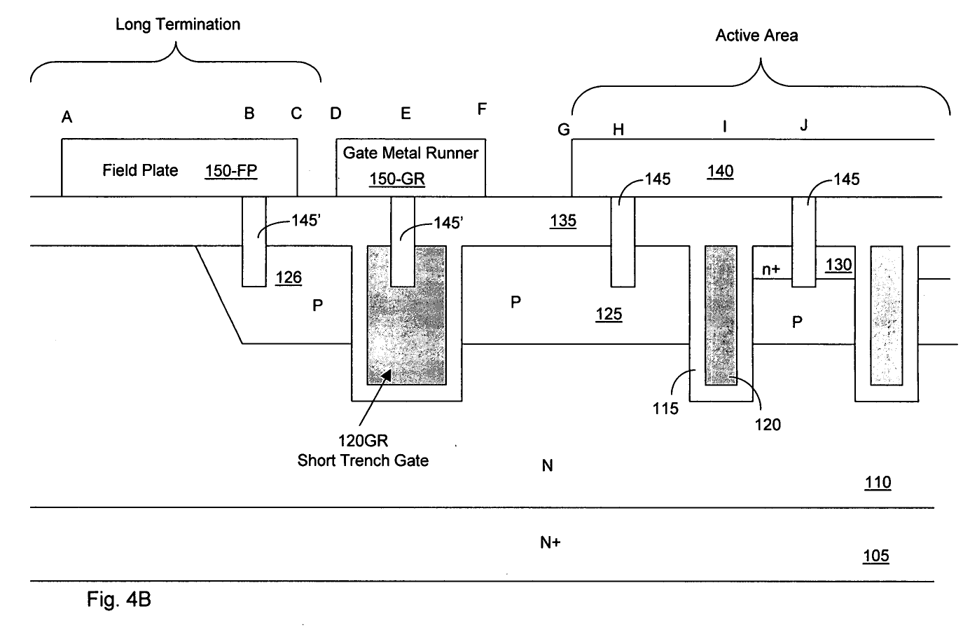

Please refer to FIG. 4A for a top view to illustrate the positions of the trenched gate contact plugs 145′ and the trenched source contact plugs 145 composed of tungsten surrounded by Ti/TiN barrier layer. The contact openings in the termination area above the gate runner trenches 120-GR are opened as discontinuous openings to avoid the intersection areas between the trenches extending from the active cell area to the termination area. The tungsten gate contact plugs 145′ are formed with shapes as square, rectangular, circular contact plugs. These contact plugs formed to contact the gate runner metal 155 are disposed at a distance S away from the T-intersections interfaced between the extended trenches 120 from the source metal 140 to the field plate 150. Again, the distance S is greater than half of the width of the trench-gate finger “a”, i.e., S>(½)*a. These trenched gate contact plugs 145′ are therefore disposed away from the polysilicon holes 160. The problem of source-to-drain short circuit caused by the etch-through holes and tungsten filling into the etch-through holes is therefore prevented. In order to allow the P-body region 126 to connect to the body-dopant region underneath the field plate, FIGS. 4A and 4B show a metal cross over of continuous trenched gate 120-Cross as shown in FIG. 4A. The metal cross over implemented as continuous trenched gate 120-Cross allows the P-body region 125 in the source regions 125 to connect to the P-body region 126 near and underneath the metal field plate. The cross over metal provides a connection allows the P-body 125 in source region to the P-body regions 126 underneath Metal field plate 150 as shown FIG. 4B.

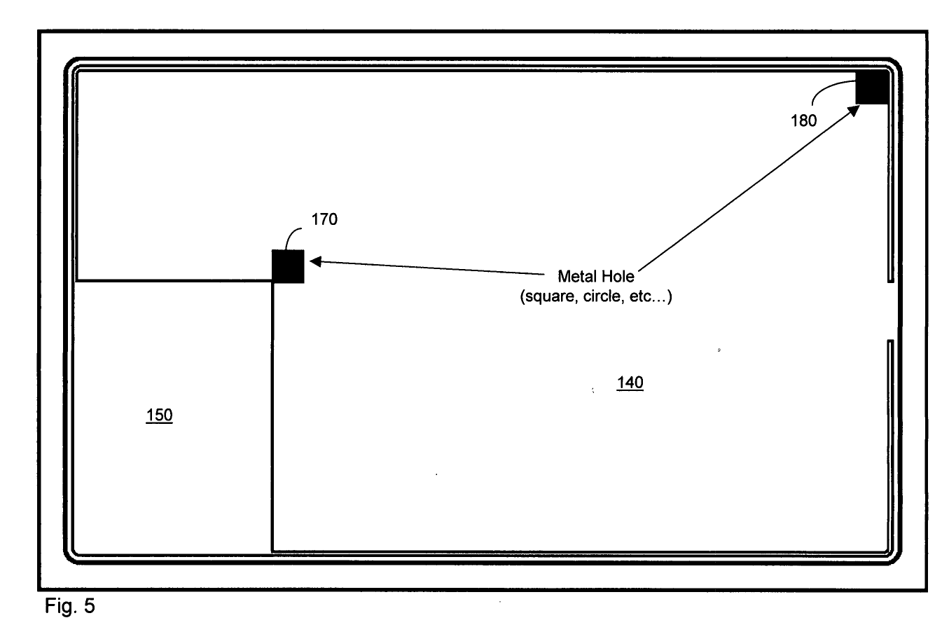

FIG. 5 is a top view of a MOSFET device of this invention showing a source metal 140 and a gate metal 150. As discussed above, with the tungsten contact plugs now filled in the contact trenches, excellent planarization process is achieved for both the source contact and the gate contact areas. For the purpose of differentiating the source metal and gate metal to carry out the wire-bonding process, a metal hole 170 is formed at the intersection corner between the source metal 140 and the gate metal 150. Another hole 180 is also formed at the diagonal corner oppose the intersectional hole 170. The metal holes 170 and 180 can be of different shapes such as square, circular, rectangular or hexagonal, etc., to provide area recognition to differentiate the source metal 140 and the gate metal 150.

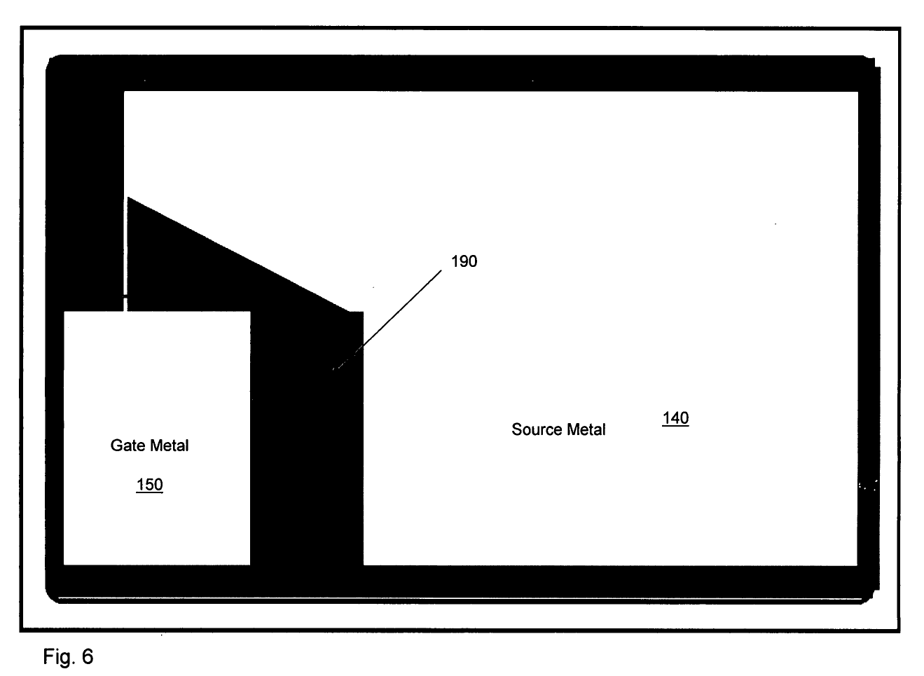

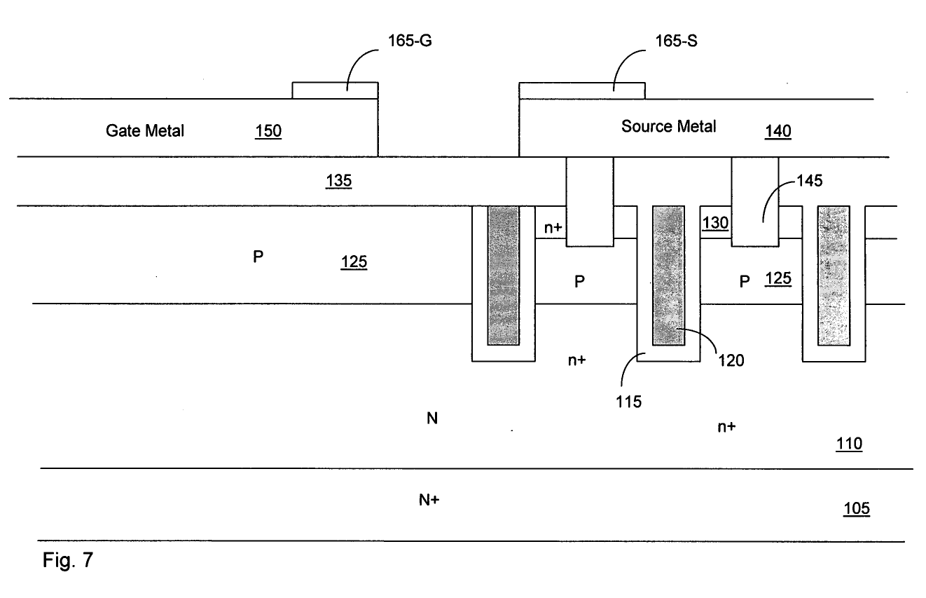

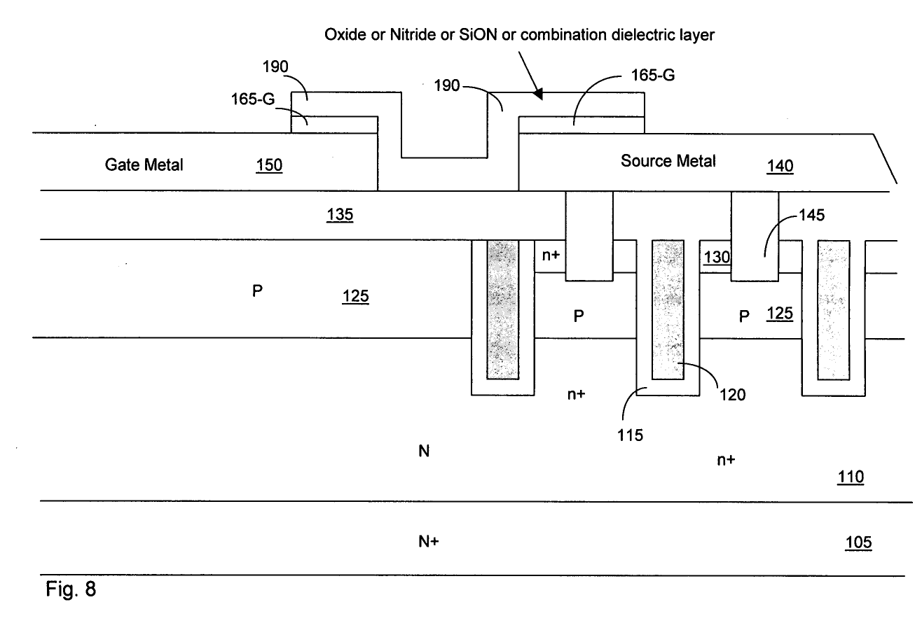

FIG. 6 is a top view of another MOSFET device of this invention showing a source metal 140 and a gate metal 150 separated by a dark color area 190. The dark color area 190 may be a layer composed of TiN or TiN/Oxide, or TiN/SiON or TiN/Nitride, or TiN/Combination of oxide, Nitride, and SiON. Again, the dark color area 190 serves the function of area recognition to differentiate the source metal 140 from the gate metal 150 in the wire-bonding process. FIG. 7 and FIG. 8 are two cross sectional views for showing the process to form the dark color are 190. In FIG. 7, a TiN layer 165-S and 165-G is formed and patterned on top of the source metal 140 and the gate metal 150 respectively. Then, in FIG. 8, an oxide, a nitride or SiON or combination of dielectric layer 190 of dark color is deposited and patterned on top of the device to provide area recognition.

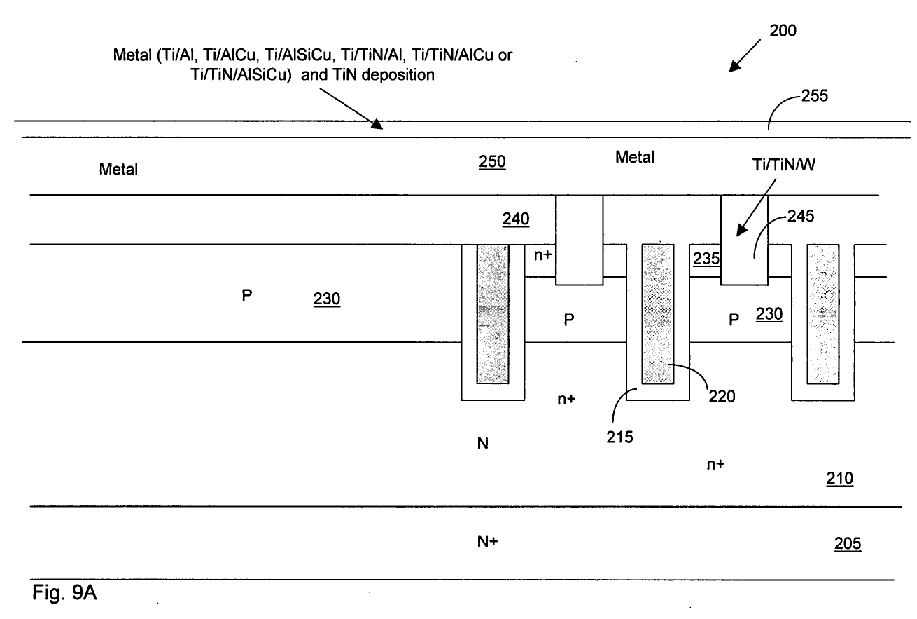

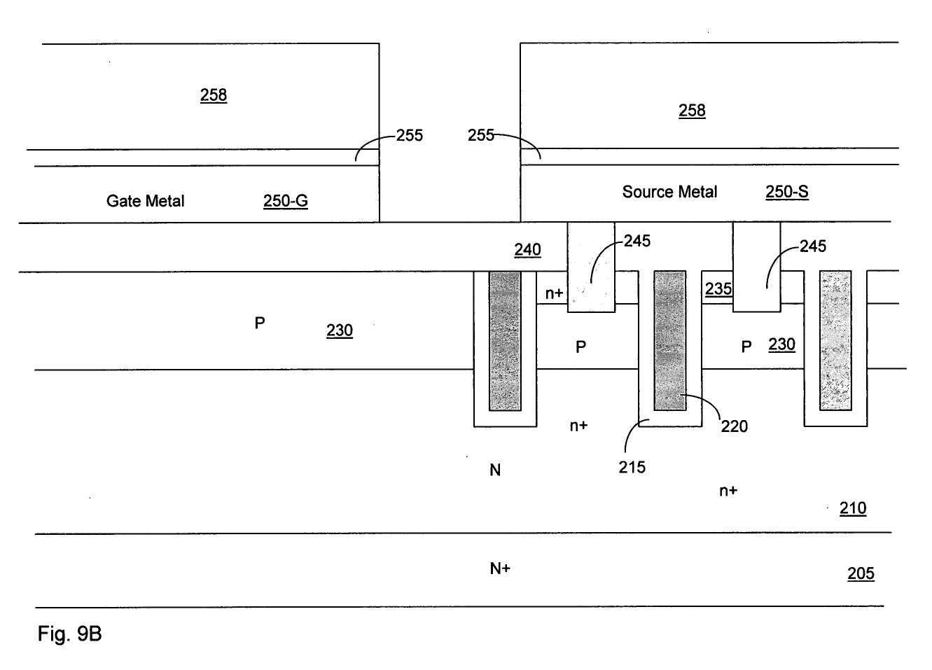

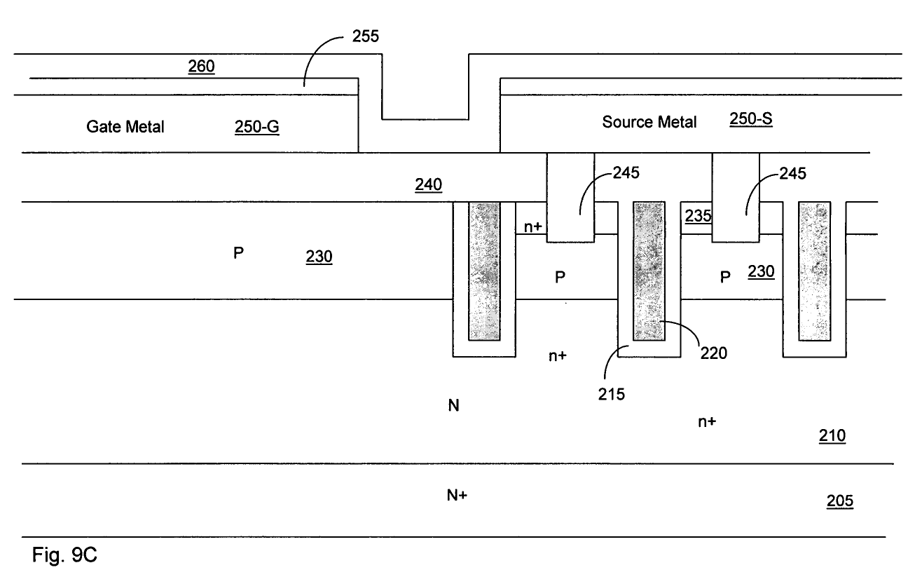

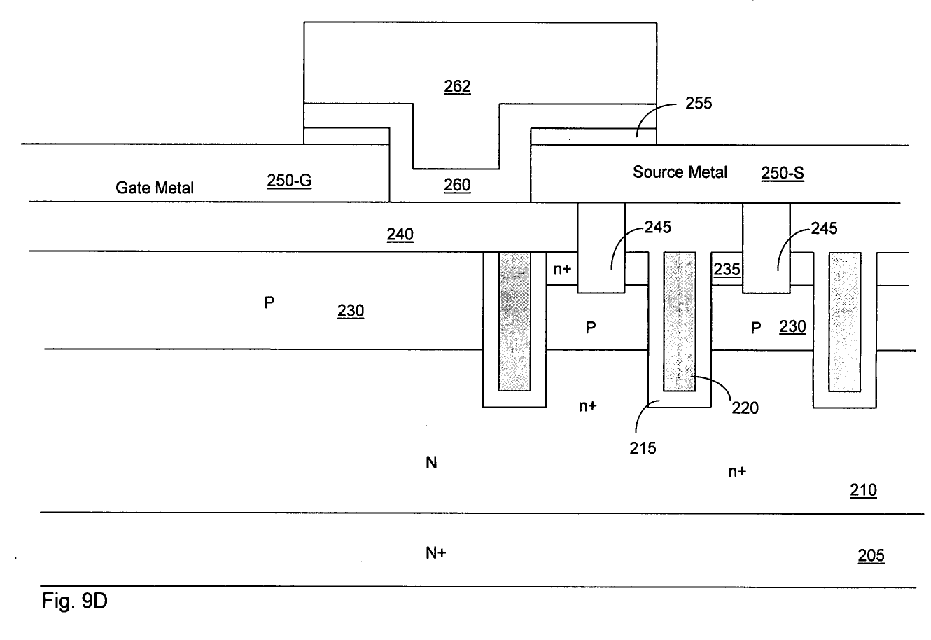

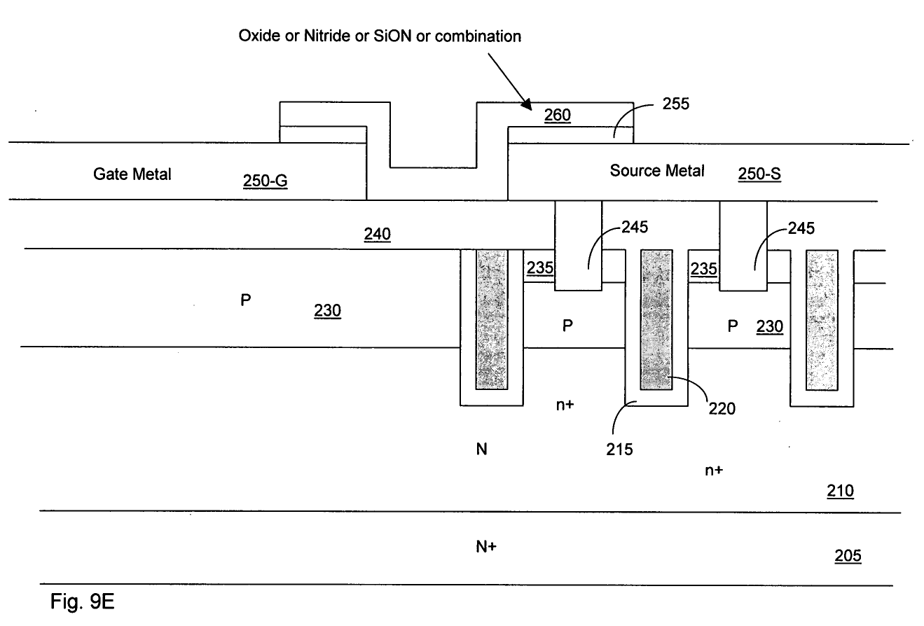

Referring to FIGS. 9A to 9E for a serial of side cross sectional views to illustrate the fabrication steps to form the MOSFET device as that shown in FIG. 3. FIG. 9A shows a partially fabricated MOSFET device 200 processed on a substrate 205 supporting an epitaxial layer 210 with trenched gates 220 disposed in trenches insulated with gate oxide layer 215. The body regions 230 encompass source regions 235 are formed between the trenched gates 220. An insulation layer 240 covers the top surface with trenched contact openings opened through the insulation layer 240 and filled with source contact plugs 245 composed of tungsten and surrounded by barrier layer, e.g., Ti/TiN barrier layer. A metal layer 250 is formed on top of the insulation layer 240 and in electrical contact to the source contact plugs 245. The metal layer 250 may compose of Ti/Al, Ti/AlCu, Ti/AlSiCu, Ti/TiN/Al, Ti/TiN/AlCu, or Ti/TiN/AlSiCu. A thin layer 255 composed of TiN is then formed on top of the metal layer 250. In FIG. 9B, a metal mask 258 is applied to etch the metal 250 and the titanium layer 255 into a gate metal 250-G and source metal 250-S. The metal mask 258 is shaped as that shown in FIGS. 3B, 3C, and 4 depending on alternated embodiments to placing the tungsten contact plugs 145′ in different locations away from the trench intersection areas. Furthermore, the metal mask 258 also provides patterns of opening holes 170 and 198 as that shown in FIG. 5. These metal holes 170 opened at the corner of the gate metal and the hole 180 at a corner of the source diagonally opposed to the hole 170 are provided for source-gate metal area recognition by a wire bonding equipment.

In FIG. 9C, the metal mask 258 is removed and a passivation layer 260 is deposited over the metal layers 250 and 255. In FIG. 9D, a passivation layer mask 262 is applied to etch and pattern the passivation layer 260. In FIG. 9E, the passivation layer mask 262 is removed and the oxide, nitride or SiON or combination to provide a dark color area to separate the source metal 250-S from the gate metal 250-G. The colored separation area 190 as that shown in FIG. 9 allows the wire bonding equipment to differentiate the source metal from the gate metal. Enhancement of area recognition in the wire-bonding process can be achieved.

According to FIGS. 9A to 9E, and above drawings and descriptions, this invention describe a method for fabricating a trenched semiconductor power device. The method includes steps of forming a trenched gate as an extended continuous trench surrounding a plurality of transistor cells in an active cell area and extending as trench-gate fingers to intersect with a trenched gate underneath gate runner metal near a termination area having a trench intersection region. The method further includes steps of forming each of said transistor cells surrounded by said trenched gate with a body region encompassing a source region therein with a drain region formed on a bottom surface of a substrate. The method further includes a step of forming an overlying insulation layer and opening at least a gate contact trench penetrating through the insulation layer and extending into a trench-filling material in the trenched gate under gate runner metal by opening the gate contact trench in an area away from the trench intersection region to prevent a vulnerability to a polysilicon void developed in the trench intersection region. In another embodiment, the method further includes a step of opening at least a source contact trenches through the insulation layer for contacting the source region in at least one of the transistor cells and filling the gate contact trench and source contact trench with a gate contact plug and a source contact plug. The method further includes another step of forming a metal layer on top of the insulation layer and patterning the metal layer into a gate metal and a source metal to electrically contact respectively to the gate contact plug and the source contact plug and forming the gate metal and source metal with a pattern recognition mark for wire bonding.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A trenched semiconductor power device comprising a trenched gate disposed in an extended continuous trench surrounding a plurality of transistor cells in an active cell area and extending as trench-gate fingers to intersect with a trenched gate underneath gate runner metal near a termination area, wherein:
at least one of said trench-gate fingers intersect with said trenched gate underneath gate runner metal in said termination area having trench intersection regions vulnerable to have a polysilicon void developed therein; and
at least a gate contact trench opened through an insulation layer covering said semiconductor power device wherein said gate contact trench penetrating from said insulation layer and extending into a trench-filling material in said trenched gate underneath gate runner metal and said gate contact trench is opened in an area away from said trench intersection regions.

2. The trenched semiconductor power device of claim 1 wherein:
said trench intersection regions constituting a T-shaped intersection region.

3. The trenched semiconductor power device of claim 1 wherein:
said gate contact trench is filled with a conductive gate contact plug.

4. The trenched semiconductor power device of claim 1 wherein:
said gate contact trench is filled with a tungsten gate contact plug.

5. The trenched semiconductor power device of claim 1 wherein:
said gate contact trench is filled with a tungsten gate contact plug surrounded with a Ti/TiN barrier layer.

6. The trenched semiconductor power device of claim 1 wherein:
said trenched gate underneath gate runner metal is configured as an open stripe extending from and intersecting to said trench-gate fingers as an L-shaped trenched gate underneath gate runner metal with said gate contact trench opened at a distance S away from an near edge of each of said trench-gate fingers where S is greater than half of a width of said trench-gate fingers.

7. The trenched semiconductor power device of claim 1 wherein:
said trenched gate underneath gate runner metal is configured as an open stripe extending from and intersecting to said trench-gate fingers as an expanded square-shaped trenched gate underneath gate runner metal with said gate contact trench opened at a distance S away from an intersecting edge of each of said trench-gate fingers with said expanded square shaped trenched gate underneath gate runner metal where S is greater than a width of said trench-gate fingers.

8. The trenched semiconductor power device of claim 1 wherein:
said trenched gate underneath gate runner metal is configured as a no-open-end trenched gate underneath gate runner metal perpendicularly intersecting to said trench-gate fingers with said gate contact trench opened at a distance S away from an intersecting edge of each of said trench-gate fingers with said no-open-end trenched gate underneath gate runner metal where S is greater than half of a width of said trench-gate fingers.

9. The trenched semiconductor power device of claim 1 wherein:
said trenched gate underneath gate runner metal is configured as an open stripe extending from and intersecting to said trench-gate fingers as an expanded rectangular-shaped trenched gate underneath gate runner metal with said gate contact trench opened at a distance S away from an intersecting edge of each of said trench-gate fingers with said expanded rectangular shaped trenched gate underneath gate runner metal where S is greater than a width of said trench-gate fingers.

10. The trenched semiconductor power device of claim 1 wherein:
said trenched gate underneath gate runner metal is configured as an open stripe extending from and having a greater width than said trench-gate fingers wherein said open stripe allowing a body-dopant region disposed adjacent to a source region of said semiconductor power device connecting to another body dopant region underneath a gate runner metal whereby said gate runner metal can function as a field plate.

11. The trenched semiconductor power device of claim 1 wherein:
said trenched gate underneath gate runner metal is configured as an open stripe extending from and intersecting to said trench-gate fingers as an L-shaped trenched gate underneath gate runner metal having a greater width than said trench-gate fingers wherein said L-shaped open trenched gate underneath gate runner metal allowing a body region disposed adjacent to a source region of said semiconductor power device connecting to another body dopant region underneath a gate runner metal whereby said gate runner metal can function as a field plate

12. The trenched semiconductor power device of claim 1 further comprising:
a metal layer formed on top of said insulation layer and patterned into a gate metal and a source metal with a TiN/dielectric layer formed on top of said metal layer for providing a pattern recognition mark for wire bonding

13. The trenched semiconductor power device of claim 1 further comprising:
a metal layer formed on top of said insulation layer and patterned into a gate metal and a source metal with at least a pattern-recognition hole formed on predefined location of said metal layer for providing a pattern recognition mark for wire bonding

14. The trenched semiconductor power device of claim 1 further comprising:
a metal layer formed on top of said insulation layer and patterned into a gate metal and a source metal with a pattern-recognition hole formed on a intersection corner between said gate metal and source metal of said metal layer for providing a pattern recognition mark for wire bonding.

15. The trenched semiconductor power device of claim 1 further comprising:
a metal layer formed on top of said insulation layer and patterned into a gate metal and a source metal with a first pattern-recognition hole formed on a intersection corner between said gate metal and source metal and a second pattern recognition hole on a source metal corner diagonally opposite said first pattern-recognition hole in said metal layer for providing a pattern recognition mark for wire bonding.

16. The trenched semiconductor power device of claim 1 wherein:
said gate contact trench penetrating from said insulation layer and extending into a trench-filling material of doped polysilicon in said trenched gate underneath gate runner metal.

17. A trenched semiconductor power device comprising a trenched gate surrounded by a source region encompassed in a body region above a drain region disposed on a bottom surface of a substrate, wherein said semiconductor power device further comprising:
at least two contact trenches opened through an insulation layer covering said semiconductor device wherein said contact trenches extending into a trench-filling material of said trenched gate and said body region and filled with a gate contact plug and a source contact plug for electrically contact respectively to a gate metal and a source metal disposed on top of said insulation layer wherein said gate metal and source metal further include a pattern recognition mark for wire bonding.

18. The trenched semiconductor power device of claim 17 further comprising:
said pattern recognition mark further comprising a TiN/dielectric layer formed on said source metal and gate metal for providing a pattern recognition mark for wire bonding.

19. The trenched semiconductor power device of claim 17 further comprising:
said pattern recognition mark further comprising at least a pattern-recognition hole formed on predefined location of said gate metal or said source metal for providing a pattern recognition mark for wire bonding

20. The trenched semiconductor power device of claim 17 further comprising:
said pattern recognition mark further comprising a pattern-recognition hole formed on a intersection corner between said gate metal and source metal of said metal layer for providing a pattern recognition mark for wire bonding.

21. The trenched semiconductor power device of claim 17 further comprising:
said pattern recognition mark further comprising a first pattern-recognition hole formed on a intersection corner between said gate metal and source metal and a second pattern recognition hole on a source metal corner diagonally opposite said first pattern-recognition hole in said metal layer for providing a pattern recognition mark for wire bonding.

22. The trenched semiconductor power device of claim 17 wherein:
said at least two contact trenches are filled with at least two conductive contact plugs for electrically contacting said source region and said trenched gate.

23. The trenched semiconductor power device of claim 17 wherein:
said at least two contact trenches are filled with at least two tungsten contact plugs for electrically contacting said source region and said trenched gate.

24. The trenched semiconductor power device of claim 17 wherein:
said at least two contact trenches are filled with at least two tungsten contact plugs surrounded with a Ti/TiN barrier layer for electrically contacting said source region and said trenched gate.

25. The trenched semiconductor power device of claim 17 further comprising:
said pattern recognition mark further comprising a TiN/oxide layer formed on said source metal and gate metal for providing a pattern recognition mark for wire bonding.

26. The trenched semiconductor power device of claim 17 further comprising:
said pattern recognition mark further comprising a TiN/SiON layer formed on said source metal and gate metal for providing a pattern recognition mark for wire bonding.

27. The trenched semiconductor power device of claim 17 further comprising:
said pattern recognition mark further comprising a TiN/nitride layer formed on said source metal and gate metal for providing a pattern recognition mark for wire bonding.

28. The trenched semiconductor power device of claim 17 further comprising:
said pattern recognition mark further comprising a TiN/Combination of oxide, nitride and SiON layer of a different color formed on said source metal and gate metal for providing a pattern recognition mark for wire bonding.

29. A method for fabricating a trenched semiconductor power device comprising steps of forming a trenched gate as an extended continuous trench surrounding a plurality of transistor cells in an active cell area and extending as trench-gate fingers to intersect with a trenched gate underneath gate runner metal near a termination area having a trench intersection region and forming each of said transistor cells surrounded by said trenched gate with a body region encompassing a source region therein with a drain region formed on a bottom surface of a substrate, said method further comprising:
forming an overlying insulation layer and opening at least a gate contact trench penetrating through said insulation layer and extending into a trench-filling material in said trenched gate under gate runner metal by opening said gate contact trench in an area away from said trench intersection region to prevent a vulnerability to a polysilicon void developed in said trench intersection region.

30. The method of claim 29 further comprising:
opening at least a source contact trench through said insulation layer for contacting said source region in at least one of said transistor cells and filling said gate contact trench and source contact trench with a gate contact plug and a source contact plug; and
forming a metal layer on top of said insulation layer and patterning said metal layer into a gate metal and a source metal to electrically contact respectively to said gate contact plug and said source contact plug and forming said gate metal and source metal with a pattern recognition mark for wire bonding.

31. The trenched semiconductor power device of claim 30 wherein:
said step of filling said gate contact trench and source contact trench comprising step of filling said gate contact trench with a tungsten gate contact plug and a tungsten source contact plug.
